(19) United States
(12) Patent Application Publication
(10) Pub. No.: US 2025/0385164 A1
(43) Pub. Date: Dec. 18, 2025

(54) SEMICONDUCTOR DEVICE AND METHOD OF MANUFACTURING THE SAME

(71) Applicant: SUMITOMO ELECTRIC INDUSTRIES, LTD., Osaka (JP)

(72) Inventors: Tatsuya HASHINAGA, Osaka (JP); Yutaka MORIYAMA, Osaka (JP)

(21) Appl. No.: 19/201,002

(22) Filed: May 7, 2025

(30) Foreign Application Priority Data
Jun. 17, 2024 (JP) 2024-097733

(51) Int. Cl. H01L 23/495; H01L 23/66

(52) U.S. Cl. CPC H01L 23/49562; H01L 23/49582; H01L 23/49589; H01L 23/66

(57) ABSTRACT

A semiconductor device includes a semiconductor element, a first metal layer electrically connected to the semiconductor element, a bonding layer bonded onto the first metal layer and formed of a sintered metal or solder, a lead bonded onto the bonding layer, and a second metal layer provided in a first hole penetrating the bonding layer, the second metal layer electrically connecting the first metal layer to the lead.

### CROSS REFERENCE TO RELATED APPLICATIONS

This application is based on and claims priority to Japanese Patent Application No. 2024-097733 filed on Jun. 17, 2024, and the entire contents of the Japanese patent application are incorporated herein by reference.

### TECHNICAL FIELD

The present disclosure relates to a semiconductor device and a method of manufacturing the same.

### BACKGROUND

A semiconductor device as known in the art includes a semiconductor chip mounted on a base portion and covered with an insulating layer, and an interconnect electrically connected to the semiconductor chip and provided on the insulating layer, wherein the interconnect is electrically connected to a terminal (for example, patent literature 1: Japanese Unexamined Patent Application Publication No. 2023-133676).

### SUMMARY

A semiconductor device according to an embodiment of the present disclosure includes a semiconductor element, a first metal layer electrically connected to the semiconductor element, a bonding layer bonded onto the first metal layer and formed of a sintered metal or solder, a lead bonded onto the bonding layer; and a second metal layer provided in a first hole penetrating the bonding layer, the second metal layer electrically connecting the first metal layer to the lead.

A method of manufacturing a semiconductor device according to an embodiment of the present disclosure includes forming a bonding layer formed of a sintered metal or solder on a first metal layer electrically connected to a semiconductor element, bonding a lead onto the bonding layer, and forming a second metal layer provided in a first hole penetrating the bonding layer so as to electrically connect the first metal layer to the lead.

### BRIEF DESCRIPTION OF THE DRAWINGS

FIG. 1 is a cross-sectional view of a semiconductor device according to a first embodiment.

FIG. 2 is a cross-sectional view of a semiconductor device according to a comparative embodiment.

FIG. 3 is a circuit diagram of a semiconductor device according to a second embodiment.

FIG. 4A is a plan view of a semiconductor device according to a second embodiment.

FIG. 4B is an A-A cross-sectional view of FIG. 4A.

FIG. 5A is a plan view of a bonding layer and its vicinity in a second embodiment.

FIG. 5B is an A-A cross-sectional view of FIG. 5A.

FIG. 6 is a cross-sectional view of another example of a bonding layer and its vicinity in a second embodiment.

FIG. 7A is a plan view showing a method of manufacturing a semiconductor device according to a second embodiment.

FIG. 7B is an A-A cross-sectional view of FIG. 7A.

FIG. 8 is a cross-sectional view showing a method of manufacturing a semiconductor device according to a second embodiment.

FIG. 9A is a plan view showing a method of manufacturing a semiconductor device according to a second embodiment.

FIG. 9B is an A-A cross-sectional view of FIG. 9A.

FIG. 10 is a cross-sectional view showing a method of manufacturing a semiconductor device according to a second embodiment.

FIG. 11 is a cross-sectional view showing a method of manufacturing a semiconductor device according to a second embodiment.

FIG. 12 is a cross-sectional view showing a method of manufacturing a semiconductor device according to a second embodiment.

FIG. 13A is a plan view showing a method of manufacturing a semiconductor device according to a second embodiment.

FIG. 13B is an A-A cross-sectional view of FIG. 13A.

FIG. 14A is a plan view showing a method of manufacturing a semiconductor device according to a second embodiment.

FIG. 14B is an A-A cross-sectional view of FIG. 14A.

FIG. 15A is a plan view showing a method of manufacturing a semiconductor device according to a second embodiment.

FIG. 15B is an A-A cross-sectional view of FIG. 15A.

FIG. 16 is an enlarged view of the bonding layer and its vicinity of FIG. 15B.

FIG. 17A is a plan view showing a method of manufacturing a semiconductor device according to a second embodiment.

FIG. 17B is an A-A cross-sectional view of FIG. 17A.

FIG. 18 is an enlarged view of the bonding layer and its vicinity of FIG. 17B.

FIG. 19A is a plan view showing a method of manufacturing a semiconductor device according to a second embodiment.

FIG. 19B is an A-A cross-sectional view of FIG. 19A.

FIG. 20 is an enlarged view of the bonding layer and its vicinity of FIG. 19B.

### DETAILED DESCRIPTION

It is conceivable that a lead as a terminal to be electrically connected to the semiconductor element is bonded onto the interconnect by using a bonding layer. However, since the bonding layer has low conductivity, the resistance between the semiconductor element and the lead is increased.

An object of the present disclosure is to provide a semiconductor device capable of reducing the resistance between a semiconductor element and a lead, and a method of manufacturing the same.

### Description of Embodiments of Present Disclosure

First, embodiments of the present disclosure will be listed and described.

(1) A semiconductor device according to an embodiment of the present disclosure includes a semiconductor element, a first metal layer electrically connected to the semiconductor element, a bonding layer bonded onto the first metal layer and formed of a sintered metal or solder, a lead bonded onto the bonding layer and a second metal layer provided in a first hole penetrating the bonding layer, the second metal layer electrically connecting the first metal layer to the lead. This can reduce the electrical resistance between the first metal layer and the lead, and can improve the characteristics of the semiconductor device.

(2) In the above (1), the second metal layer may have a conductivity higher than a conductivity of the bonding layer. This can reduce the electrical resistance between the first metal layer and the lead.

(3) In the above (1) or (2), the bonding layer may be a sintered metal including a resin. Thus, even when the conductivity of the bonding layer is low, the electrical resistance between the first metal layer and the lead can be reduced.

(4) In any one of the above (1) to (3), the lead may have a second hole penetrating the lead. The second hole may overlap the first hole when viewed in a stacking direction of the second metal layer and the lead. Thus, the first hole can be formed.

(5) In the above (4), the first hole may be smaller than the second hole when viewed in the stacking direction. The semiconductor device may include a third metal layer provided on the bonding layer in the second hole and electrically connecting the second metal layer to the lead. This allows the second metal layer and the lead to be electrically connected.

(6) The semiconductor device according to any one of the above (1) to (5) may further include a base on which the semiconductor element is mounted, the base being conductive, and an insulating layer provided on the base so as to cover the semiconductor element, the first metal layer being provided on an upper surface of the insulating layer. This can improve the characteristics.

(7) The semiconductor device according to the above (6) may further include an electronic component provided on the insulating layer and electrically connected to the lead or the semiconductor element. This allows for miniaturization.

(8) The semiconductor device according to the above (6) or (7) may further include a passive element mounted on the base. The lead may include an input lead and an output lead. The semiconductor element may include a transistor configured to amplify a high frequency signal input to the input lead and output an amplified high frequency signal from the output lead. The first metal layer may include a first interconnect electrically connecting the input lead to the transistor and a second interconnect electrically connecting the output lead to the transistor. The passive element may include a capacitor electrically connected to the first interconnect or the second interconnect. This can improve high frequency characteristics.

(9) In any one of the above (1) to (7), the semiconductor element may be an element for a high frequency signal. This can improve high frequency characteristics.

(10) A method of manufacturing a semiconductor device according to an embodiment of the present disclosure includes forming a bonding layer formed of a sintered metal or solder on a first metal layer electrically connected to a semiconductor element, bonding a lead onto the bonding layer, and forming a second metal layer in a first hole penetrating the bonding layer so as to electrically connect the first metal layer to the lead. Thus, the second metal layer for electrically connecting the first metal layer to the lead can be formed. Thus, the electrical resistance between the first metal layer and the lead can be reduced, and the characteristics of the semiconductor device can be improved.

(11) In the above (10), the lead may have a second hole penetrating the lead. The method of manufacturing the semiconductor device may include forming the first hole in the bonding layer so as to be connected to the second hole and penetrate the bonding layer, after the bonding the lead and before the forming the second metal layer. Thus, the first hole can be formed.

### Details of Embodiments of Present Disclosure

Specific examples of a semiconductor device and a method of manufacturing the same according to embodiments of the present disclosure will be described below with reference to the drawings. The present disclosure is not limited to these examples, but is defined by the appended claims, and is intended to include all modifications within the scope and meaning equivalent to the appended claims.

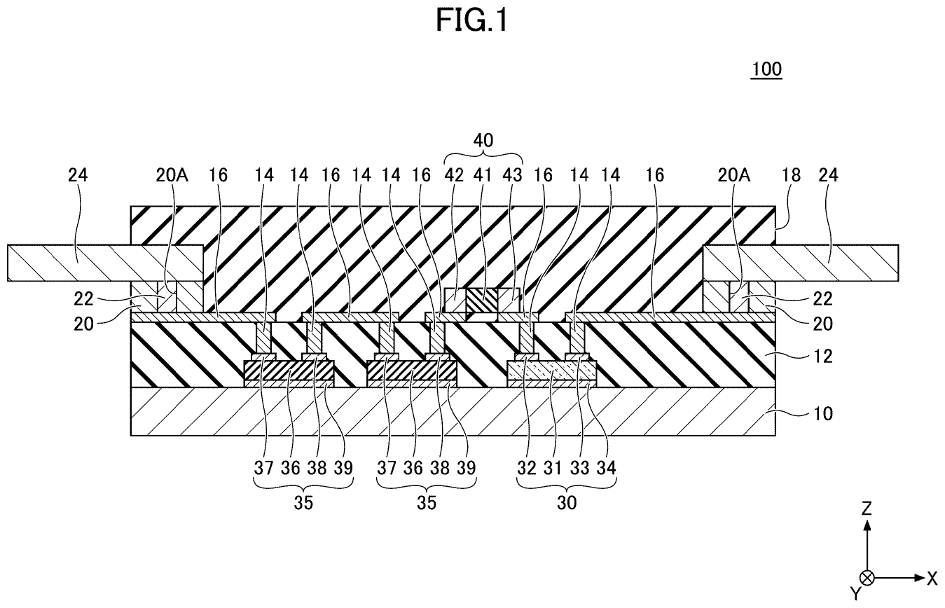

FIG. 1 is a cross-sectional view of a semiconductor device according to a first embodiment. A stacking direction of a bonding layer 20 and a lead 24, which is a thickness 25 direction of a base 10, is defined as a Z direction, an arrangement direction of the lead 24 is defined as an X direction, and a direction orthogonal to the X direction and the Z direction is defined as a Y direction. As shown in FIG. 1, a semiconductor device 100 includes the base 10, insulating layers 12 and 18, a via 14, a metal layer 16, the bonding layer 20, a metal layer 22, the lead 24, a semiconductor element 30, a passive element 35, and an 30 electronic component 40.

The semiconductor element 30 and the passive element 35 are mounted on the base 10. The semiconductor element 30 includes a substrate 31, electrodes 32 and 33 provided on an upper surface of the substrate 31, and an electrode 34 provided on a lower surface of the substrate 31. The passive element 35 includes electrodes 37 and 38 provided on an upper surface of a substrate 36 and an electrode 39 provided on a lower surface of the substrate 36. The electrodes 34 and 39 are bonded onto the base 10 by using, for example, a conductive bonding layer.

The insulating layer 12 is provided on the base 10 so as to cover the semiconductor element 30 and the passive element 35. The vias 14 penetrate the insulating layer 12 and are electrically connected to the electrodes 32 and 33 of the semiconductor element 30 and the electrodes 37 and 38 of the passive element 35. The metal layer 16 is provided on the insulating layer 12. The metal layer 16 is electrically connected to the electrodes 32 and 33 of the semiconductor element 30 and the electrodes 37 and 38 of the passive element 35 through the vias 14. The electronic component 40 is mounted on the metal layer 16. The electronic component 40 includes a body 41 and electrodes 42 and 43. The electrodes 42 and 43 are provided on the surface of the body 41. The electrodes 42 and 43 are bonded onto the metal layer 16, for example, by using a conductive bonding layer.

The bonding layer 20 is bonded onto the metal layer 16. The lead 24 is bonded onto the bonding layer 20. The bonding layer 20 has a hole 20A penetrating the bonding layer 20 in the Z direction. The metal layer 22 is provided in the hole 20A and electrically connects the metal layer 16 to the lead 24. The insulating layer 18 is provided on the insulating layer 12 so as to cover the metal layer 16, the bonding layer 20, a part of the lead 24, and the electronic component 40. The part of the lead 24 extends from the insulating layer 18 in the X direction and is exposed from the insulating layer 18.

The base 10 is conductive at least on its upper surface, and is a metal plate such as a copper plate or a laminated plate of copper, molybdenum, and copper. The insulating layers 12 and 18 are made of resin such as epoxy resin. The via 14 and the metal layers 16 and 22 are metal layers such as copper layers. The bonding layer 20 is a sintered metal or solder. The sintered metal is obtained by sintering a conductive paste such as a silver paste, a copper paste, a gold paste, or a gold-tin paste. The solder is, for example, a tin-silver-copper solder, a tin-silver solder, or gold-tin. The lead 24 is made of, for example, a copper-based material or an iron-based material.

The semiconductor element 30 is a semiconductor chip and includes a transistor such as a field effect transistor (FET). The substrate 31 is, for example, a semiconductor substrate. The electrodes 32, 33, and 34 are metal layers made of, for example, gold, copper, or aluminum.

The passive element 35 is a passive chip, and includes, for example, a capacitor or an inductor. The substrate 36 is a dielectric substrate, which is, for example, an alumina substrate or a barium titanate substrate. The electrodes 32, 33, and 34 are metal layers made of, for example, gold, copper, aluminum, or nickel. The electronic component 40 is, for example, a chip capacitor, a chip inductor, or a chip resistor, which is a discrete component.

### Comparative Embodiment

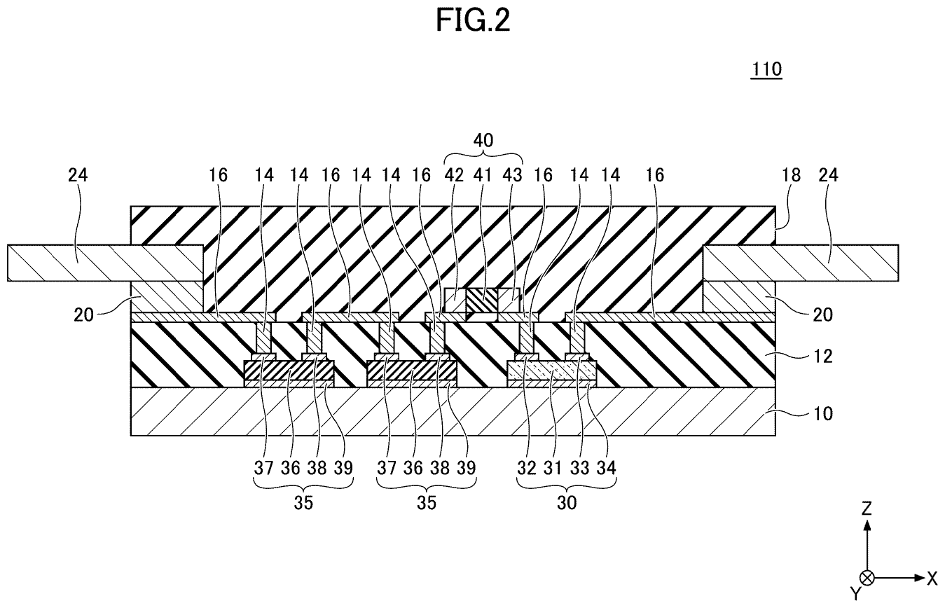

FIG. 2 is a cross-sectional view of a semiconductor device according to a comparative embodiment. As shown in FIG. 2, in a semiconductor device 110 according to the comparative embodiment, the metal layer 22 is not provided in the bonding layer 20.

As shown in the semiconductor device 110 according to the comparative embodiment, the bonding layer 20 is used to bond the lead 24 to the metal layer 16. The bonding layer 20 has low conductivity. The conductivity of a sintered metal obtained by sintering a conductive paste, is, for example, 0.1×10⁶ S/m to 30×10⁶ S/m. The conductivity of solder is, for example, 6×10⁶ S/m to 9×10⁶ S/m. Thus, the electrical resistance between the lead 24 and the metal layer 16 is increased, and the resistance between the lead 24 and the semiconductor element 30 is increased. Thus, the characteristics of the semiconductor device 110 are degraded.

### Description of First Embodiment

According to the first embodiment, the metal layer 22 (the second metal layer) is provided in the hole 20A (first hole) penetrating the bonding layer 20, and electrically connects the metal layer 16 (the first metal layer) to the lead 24. Since the metal layer 22 electrically connects the metal layer 16 to the lead 24 in this manner, the electrical resistance between the metal layer 16 and the lead 24 can be reduced, and the characteristics of the semiconductor device 100 can be improved.

The metal layer 22 has a conductivity higher than a conductivity of the bonding layer 20. This can reduce the electrical resistance between the metal layer 16 and the lead 24. For example, when copper is used as the metal layer 22, the conductivity of the metal layer 22 is about 65×10⁶ S/m. The conductivity of the metal layer 22 can be at least twice, or at least five times, the conductivity of the bonding layer 20. If the conductivity of the bonding layer 20 is too low, the electrical resistance between the metal layer 16 and the lead 24 is increased. From this viewpoint, the conductivity of the metal layer 22 may be at most 10000 times the conductivity of the bonding layer 20.

Since the solder melts at a temperature equal to or higher than the melting point, the bonding layer 20 may melt during the mounting of the semiconductor device 100. Thus, a sintered metal may be used as the bonding layer 20. The sintered metal includes a resin such as an epoxy resin after curing. For example, when the bonding layer 20 is formed using a conductive paste containing a copper powder coated with silver, the content of the resin in the bonding layer 20 is 8 mass % to 10 mass %, and the content of the silver-coated copper powder in the bonding layer 20 is 90 mass % to 92 mass %. In addition, when another conductive paste is used, the content of the resin in the bonding layer 20 is 14 mass % to 16 mass %. The content of the silver-coated copper powder in the bonding layer 20 is 84 mass % to 86 mass %.

As such, when the bonding layer 20 includes the resin, the conductivity of the bonding layer 20 is reduced. Thus, the metal layer 22 is provided, so that the electrical resistance between the metal layer 16 and the lead 24 can be reduced. The content of the resin in the bonding layer 20 is, for example, 1 mass % or more, or 5 mass % or more. The content of the resin in the bonding layer 20 is, for example, 30 mass % or less, or 20 mass % or less.

The semiconductor element 30 is mounted on the conductive base 10. Mounting the semiconductor element 30 on the conductive base 10 enables the conductive base 10 to be used as a heat sink. This improves the heat dissipation. From the viewpoint of the heat dissipation, the thickness of the conductive base 10 is, for example, 1 mm or more. If a bonding wire were used for electrical connection between the semiconductor element 30 and the passive element 35 or between the semiconductor element 30 and the terminal portion, an inductance component would be added to deteriorate high frequency characteristics. Further, the current capacity could not be increased. Thus, as disclosed in patent literature 1, the terminal portion and the base portion would be formed from the same metal plate, and the metal layer 16 on the insulating layer 12 would be used to electrically connect the semiconductor element 30 to the passive element 35, or electrically connect the semiconductor element 30 to the terminal portion. This could improve high frequency characteristics. In addition, the current capacity could be increased. In such an arrangement, however, an electrical connection for the terminal portion would be provided from the side where the lower surface of the semiconductor device is situated. There is a demand for electrical connection via leads from the lateral side of a semiconductor device. When attempting to electrically connect the lead 24 to the metal layer 16, the metal layer 16 and the lead 24 are connected to each other by using the bonding layer 20 formed of a sintered metal, solder, or the like, as shown in the semiconductor device 110 of the comparative embodiment. However, since the bonding layer 20 has low conductivity, high frequency characteristics are deteriorated. Further, the current capacity cannot be increased. In consideration of this, the metal layer 22 is used to effectively improve high frequency characteristics. In addition, the current capacity can be increased. Thus, the characteristics of the semiconductor device can be improved.

The electronic component 40 is mounted above the insulating layer 12 and electrically connected to the leads 24 and the semiconductor element 30. This allows the electronic component 40 to be mounted above the semiconductor element 30 and the passive element 35, thereby reducing the size of the semiconductor device 100.

### Second Embodiment

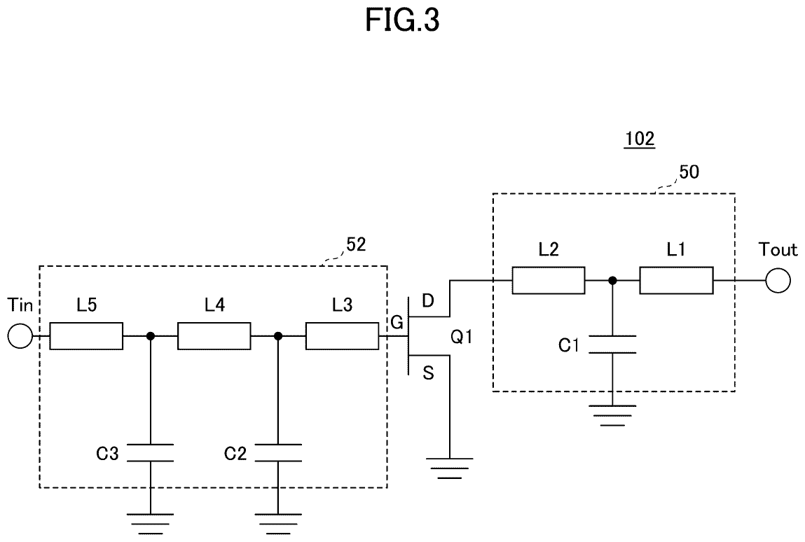

A second embodiment is an example in which a semiconductor device is used for an amplifier. FIG. 3 is a circuit diagram of a semiconductor device according to a second embodiment. As shown in FIG. 3, a semiconductor device 102 includes an input terminal Tin, an output terminal Tout, matching circuits 50 and 52, and a transistor Q1.

A high frequency signal is input to the input terminal Tin. When the semiconductor device 102 is used as a power amplifier of a base transceiver station of mobile communication, the frequencies of the high frequency signals are, for example, 0.5 GHz to 20 GHz.

A matching circuit 52 includes lines L3, L4, and L5, and capacitors C2 and C3. The lines L3 to L5 are connected in series between the gate of the transistor Q1 and the input terminal Tin. The capacitor C2 is shunt-connected to a node between the line L3 and the L4. A capacitor C3 is shunt-connected to a node between the lines L4 and L5. The matching circuit 52 matches an impedance observed when the matching circuit 52 is viewed from the input terminal Tin, with an impedance observed when the transistor Q1 is viewed from the matching circuit 52.

The transistor Q1 is an FET, and includes a source S, a drain D, and a gate G. The source S is grounded and supplied with a reference potential such as a ground potential. The gate G is electrically connected to the input terminal Tin through the matching circuit 52. The drain is electrically connected to the output terminal Tout through the matching circuit 50. The transistor Q1 amplifies the high frequency signal input to the gate G and outputs the amplified high frequency signal to the drain D.

The matching circuit 50 includes lines L1 and L2 and a capacitor C1. The lines L1 and L2 are connected in series between the drain D of the transistor Q1 and the output terminal Tout. The capacitor C1 is shunt-connected to a node between the lines L1 and L2. The matching circuit 50 matches an impedance when the matching circuit 50 is viewed from the transistor Q1 with an impedance when the output terminal Tout is viewed from the matching circuit 50. The output terminal Tout outputs the high frequency signal amplified by the transistor Q1.

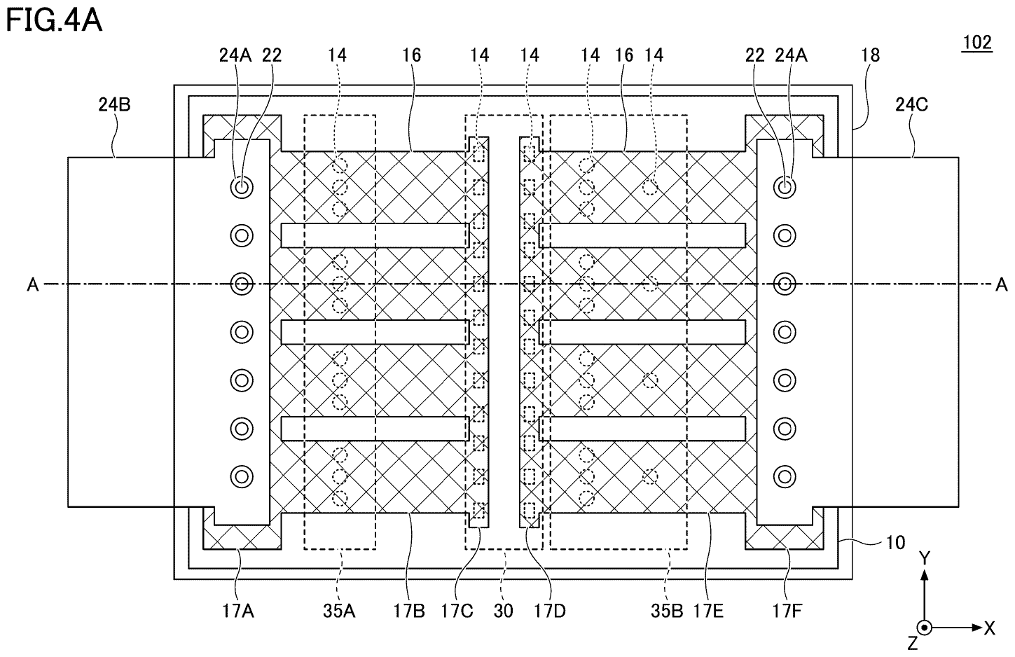

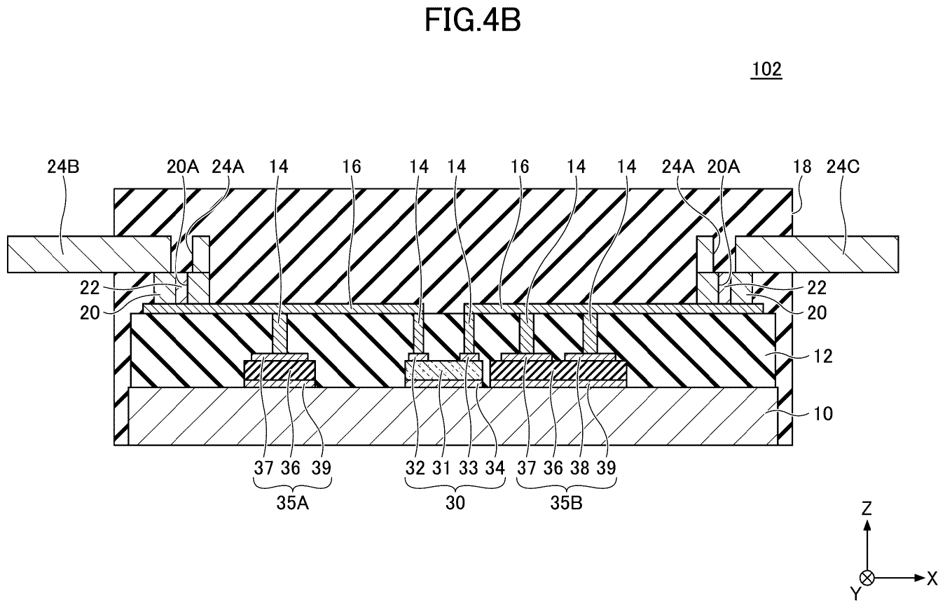

FIG. 4A is a plan view of a semiconductor device according to the second embodiment. FIG. 4B is an A-A cross-sectional view of FIG. 4A. FIG. 4A does not show the insulating layer 18, and shows the semiconductor element 30, passive elements 35A and 35B, and the vias 14 by dashed lines.

As shown in FIGS. 4A and 4B, in the semiconductor device 102, the semiconductor element 30 and the passive elements 35A and 35B are mounted on the base 10. The transistor Q1 of FIG. 3 is provided in the semiconductor element 30. The electrodes 33, 32 and 34 are electrically connected to the gate G, the drain D and the source S, respectively.

The electrode 37 is provided on the upper surface of the passive element 35A. The electrodes 37 and 39 sandwiching the substrate 36 form the capacitor C1. The electrodes 37 and 38 are provided on the upper surface of a passive element 35B. The electrodes 37 and 39 sandwiching the substrate 36 form the capacitor C2. The electrodes 38 and 39 sandwiching the substrate 36 form the capacitor C3.

The metal layer 16 includes portions 17A to 17F. The portion 17A is a portion to which a lead 24B is bonded. The portion 17C is a portion to which the electrode 32 of the semiconductor element 30 is connected through the vias 14. The portion 17B connects the portions 17A and 17C. The portion 17F is a portion to which a lead 24C is bonded. The portion 17D is a portion to which the electrode 33 of the semiconductor element 30 is connected through the vias 14. The portion 17E connects the portions 17D and 17F. The plurality of portions 17B are arranged in the Y direction, and the plurality of portions 17E are arranged in the Y direction.

The portions 17B form the lines L1 and L2. The portions 17E form lines L3 to L5. The numbers, lengths, and widths of the portions 17B and 17E can be appropriately set such that the lines L1 to L5 can obtain desired high frequency characteristics.

The lead 24B electrically connected to the portion 17A forms the output terminal Tout. The lead 24C electrically connected to the portion 17F forms the input terminal Tin. The leads 24B and 24C have holes 24A penetrating the leads 24B and 24C in the Z direction.

The transistor Q1 is, for example, a gallium nitride high electron mobility Transistor (GaN HEMT) or a laterally diffused metal oxide semiconductor (LDMOS). When the transistor Q1 is a GaN HEMT, the substrate 31 is, for example, a silicon carbide substrate. When the transistor is an LDMOS, the substrate 31 is a silicon substrate.

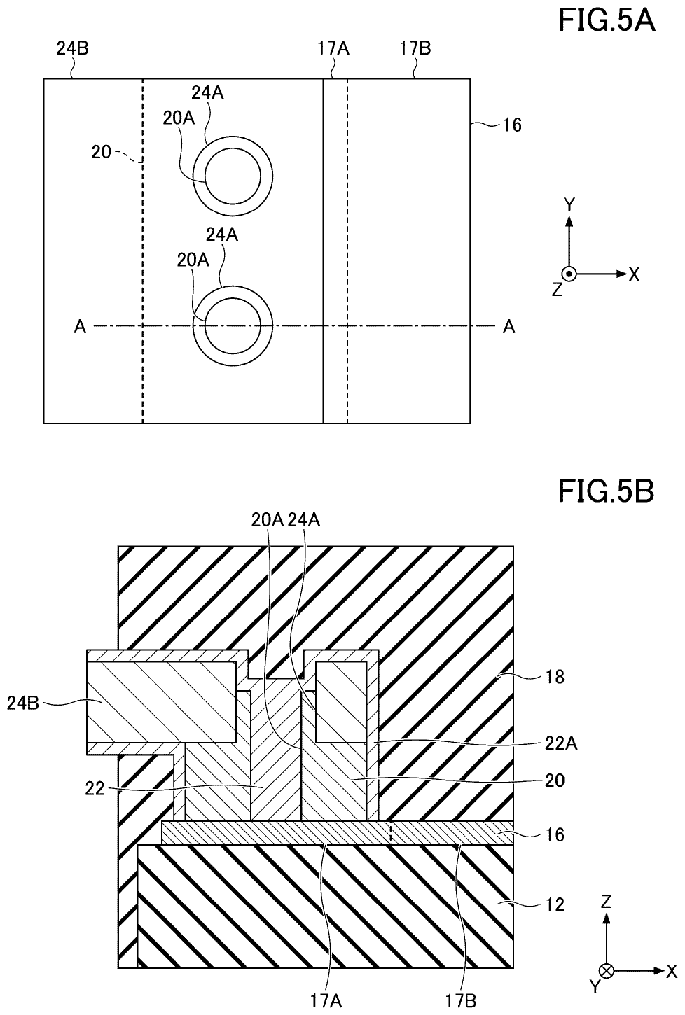

FIG. 5A is a plan view of the bonding layer and its vicinity in the second embodiment. FIG. 5B is an A-A cross-sectional view of FIG. 5A. FIG. 5A shows the metal layer 16, the bonding layer 20, the lead 24B, and the holes 20A and 24A.

As shown in FIGS. 5A and 5B, the metal layer 16 is provided on the insulating layer 12. The bonding layer 20 bonds the metal layer 16 to the lead 24B. The bonding layer 20 has the hole 20A penetrating in the Z direction. The metal layer 22 is embedded in the hole 20A. The lead 24B has the hole 24A penetrating in the Z direction. When viewed in the Z direction, the hole 24A is larger than the hole 20A, and the hole 24A and the hole 20A are connected to each other. A part of the bonding layer 20 enters the hole 24A, and a part of the hole 20A is provided in the bonding layer 20 in the hole 24A. A metal layer 22A is provided on the surfaces of the bonding layer 20 and the lead 24B. The insulating layer 18 is provided above the insulating layer 12 so as to cover the metal layer 16, the bonding layer 20, and the lead 24B.

The thickness of the base 10 is, for example, 800 μm to 1400 μm. The thickness of the insulating layer 12 is, for example, 100 μm to 300 μm. The thickness of the metal layer 16 is, for example, 35 μm to 45 μm. The thickness of the bonding layer 20 is, for example, 1 μm to 50 μm. The thickness of the lead 24 is, for example, 80 μm to 200 μm. The thickness of the insulating layer 18 is, for example, 1000 μm to 3000 μm. The widths of the insulating layer 18 in the X direction and the Y direction are, for example, from 5 mm to 20 mm. The thickness of the metal layer 22A is, for example, 8 μm to 35 μm. The diameter (width) of the hole 20A is, for example, 100 μm to 400 μm. The diameter (width) of the hole 24A is, for example, 140 μm to 500 μm.

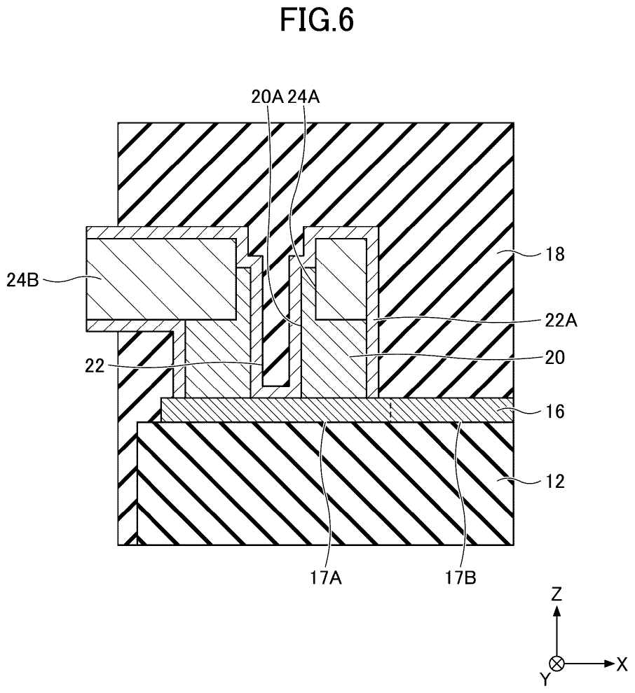

FIG. 6 is a cross-sectional view of another example of the bonding layer and its vicinity in the second embodiment, and is an A-A cross-sectional view of FIG. 5A. As shown in FIG. 6, the metal layer 22 may be provided on the side surface and the bottom surface of the hole 24A, and may not be provided in the center portion of the hole 24A. The other configuration is the same as that of FIG. 5B, and the description thereof is omitted.

### Manufacturing Method of Second Embodiment

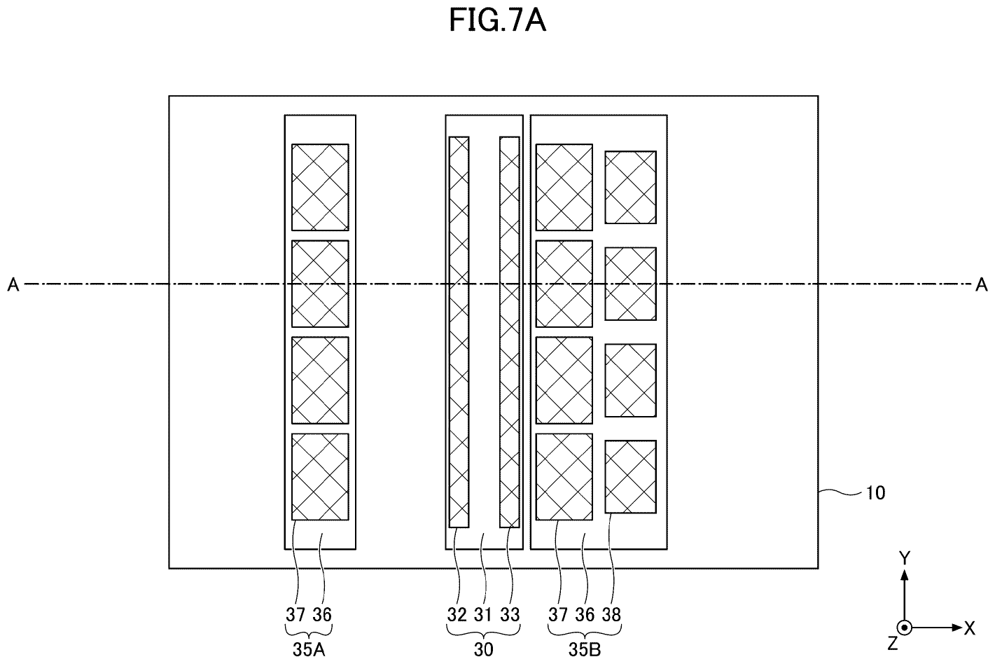

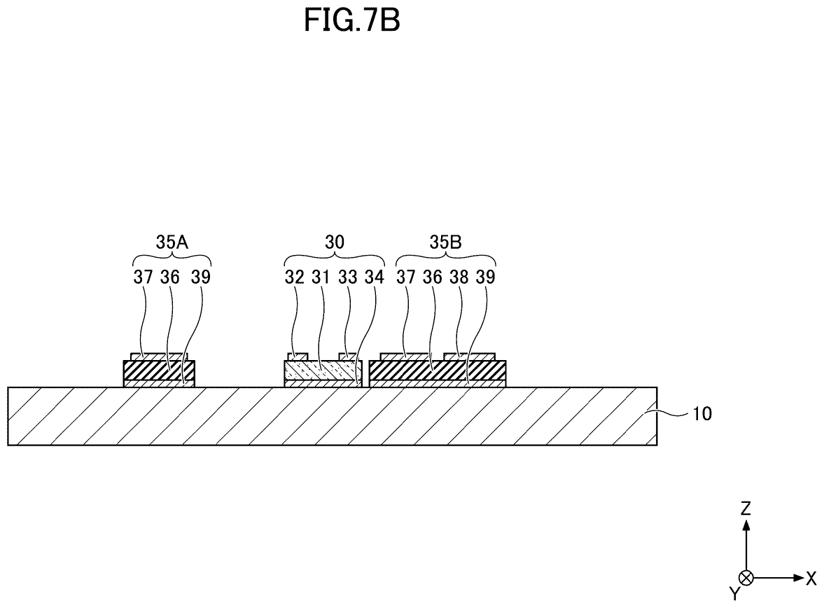

FIGS. 7A to 21 are views each showing a method of manufacturing a semiconductor device according to a second embodiment. FIG. 7A is a plan view showing a method of manufacturing a semiconductor device according to the second embodiment, and FIG. 7B is an A-A cross-sectional view of FIG. 7A. As shown in FIGS. 7A and 7B, the semiconductor element 30 and the passive elements 35A and 35B are mounted over the base 10. The electrodes 32 and 33 extend in the Y direction. The electrodes 37 and 38 are arranged in the Y direction. In the passive element 35B, the electrodes 37 and 38 are arranged in the X direction. A conductive bonding layer is used for mounting the semiconductor element 30 and the passive elements 35A and 35B. The conductive bonding layer is, for example, a conductive paste, and the semiconductor element 30 and the passive elements 35A and 35B are mounted on the base 10 with the conductive paste interposed therebetween. Thereafter, the conductive paste is sintered by heat treatment to form a conductive bonding layer.

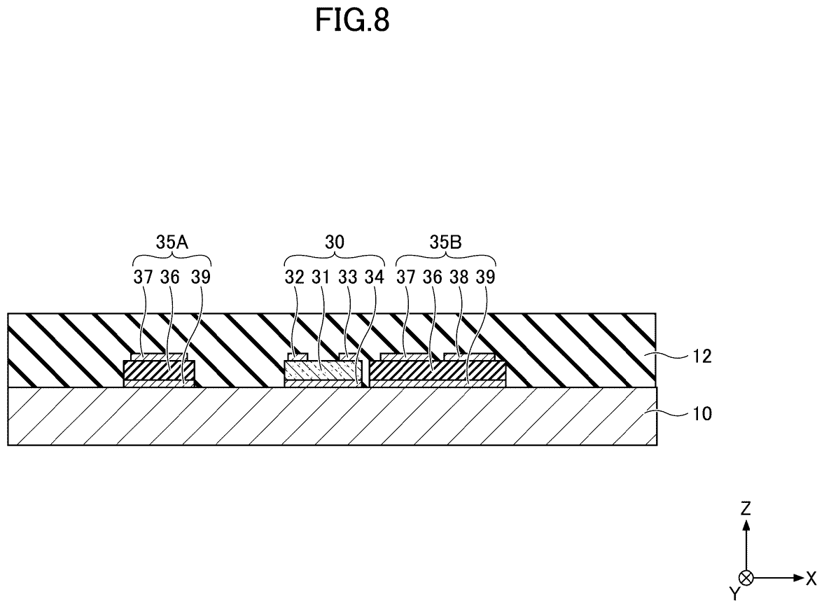

FIG. 8 is a cross-sectional view showing a method of manufacturing a semiconductor device according to the second embodiment. As shown in FIG. 8, the insulating layer 12 is provided on the base 10 so as to cover the semiconductor element 30 and the passive elements 35A and 35B. The insulating layer 12 may be formed by, for example, a lamination method or a compression molding method. Thereafter, the insulating layer 12 is cured by heat treatment. The upper surface of the insulating layer 12 may be planarized by polishing.

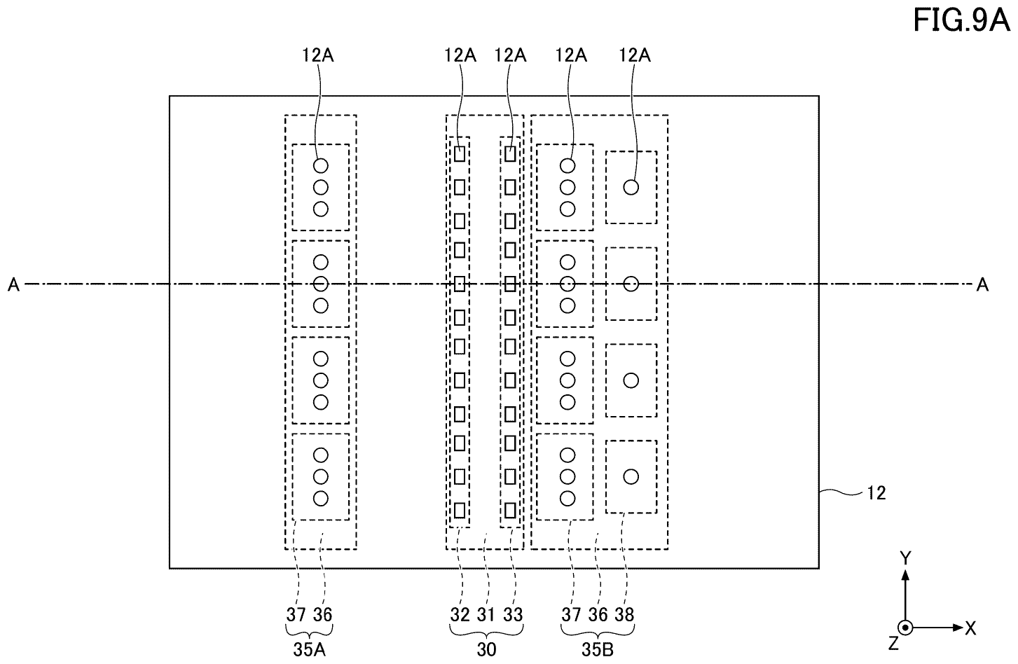

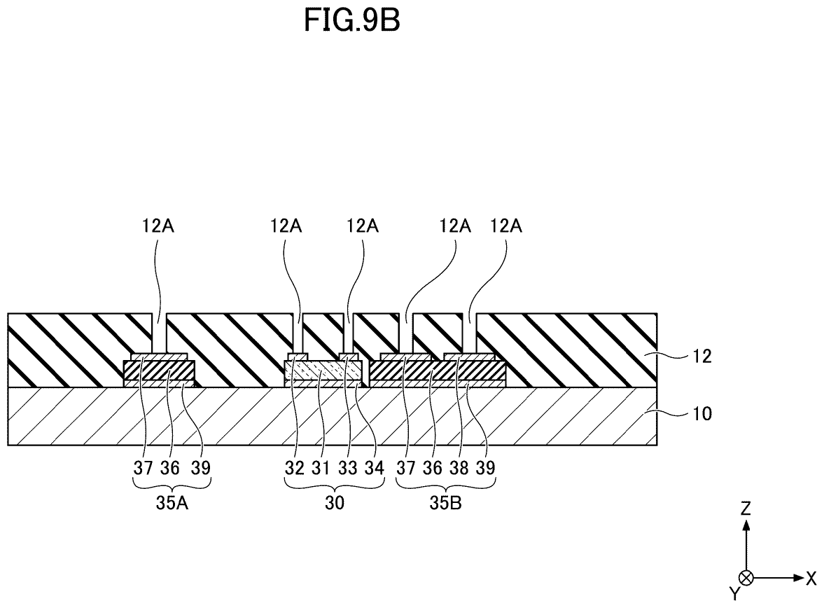

FIG. 9A is a plan view showing a method of manufacturing a semiconductor device according to the second embodiment, and FIG. 9B is an A-A cross-sectional view of FIG. 9A. As shown in FIGS. 9A and 9B, holes 12A is formed in the insulating layer 12. The hole 12A is formed by, for example, irradiation with laser light. The holes 12A expose the upper surfaces of the electrodes 32, 33, 37, and 38 through the insulating layer 12. The holes 12A connected to the electrode 32 and the holes 12A connected to the electrode 33 are arranged in the Y direction. Three holes 12A are connected to each electrode 37, and one hole 12A is connected to each electrode 38. The number of holes 12A connected to the electrodes 32, 33, 37, and 38 and the planar shape of the holes 12A can be set as appropriate.

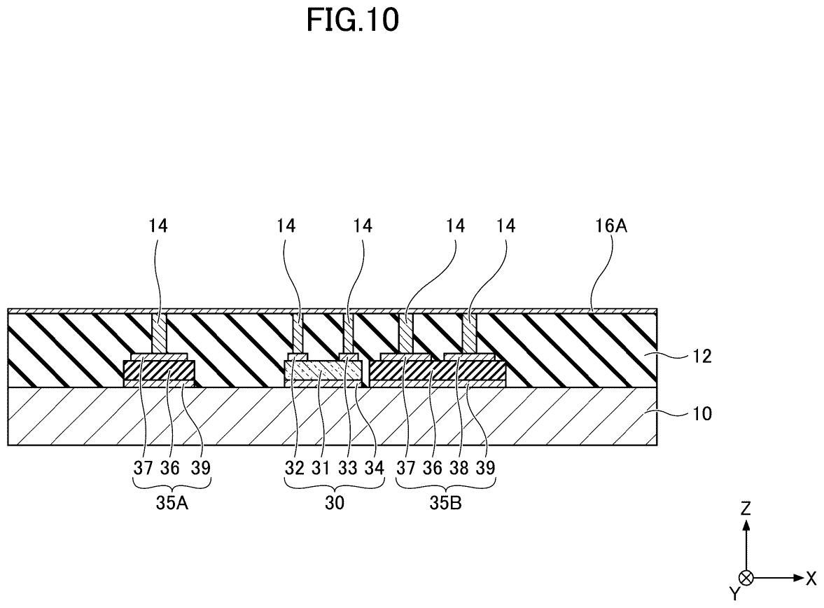

FIGS. 10 to 12 are cross-sectional views each showing a method of manufacturing a semiconductor device according to the second embodiment. As shown in FIG. 10, a desmear process is performed to remove resin residue left when the hole 12A is formed. The via 14 is formed in the hole 12A and a metal layer 16A is formed on the upper surface of the insulating layer 12 by using an electroless plating method.

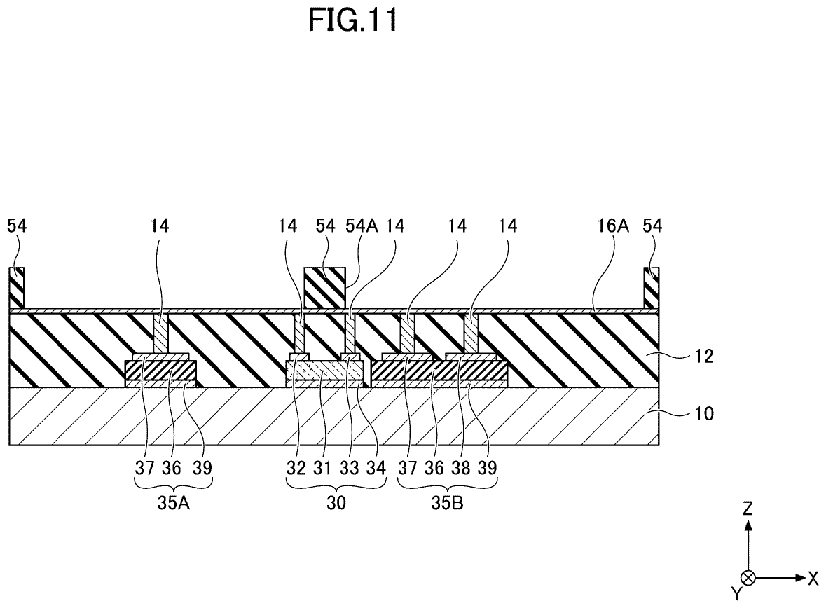

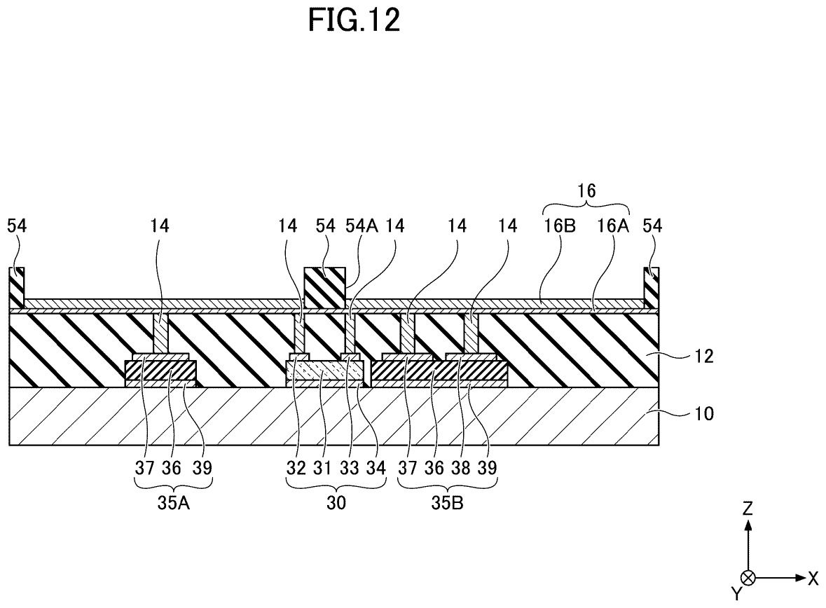

Next, as shown in FIG. 11, a mask layer 54 is formed on the metal layer 16A. The mask layer 54 is, for example, a photosensitive resin layer and is formed by a lamination method. Exposure and development are performed to form an opening 54A. Next, as shown in FIG. 12, a metal layer 16B is formed in the opening 54A by using the metal layer 16A as a seed layer and by using an electrolytic plating method.

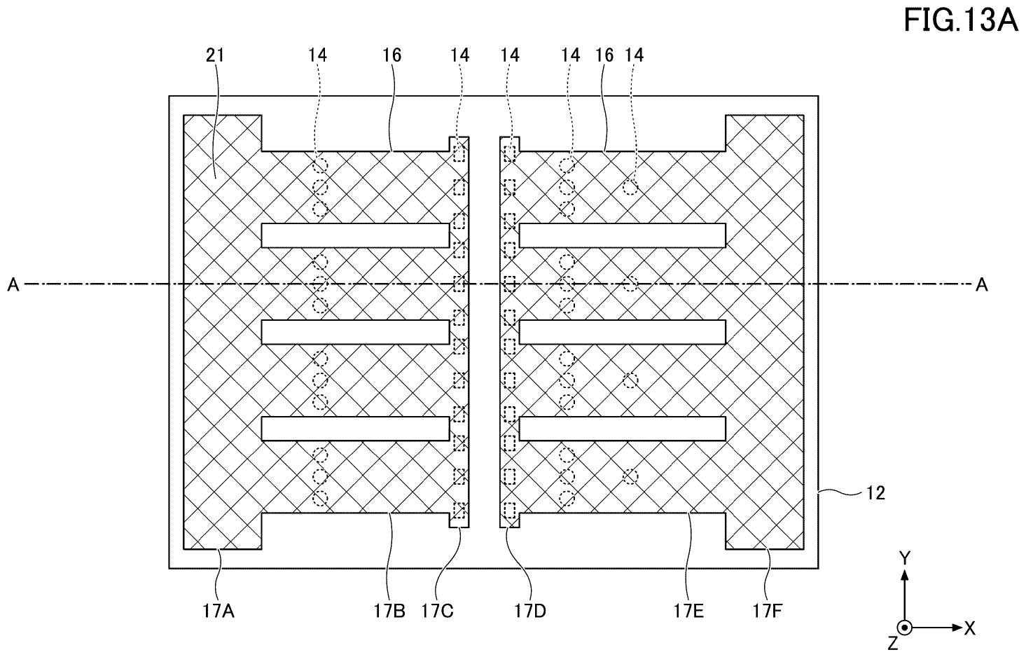

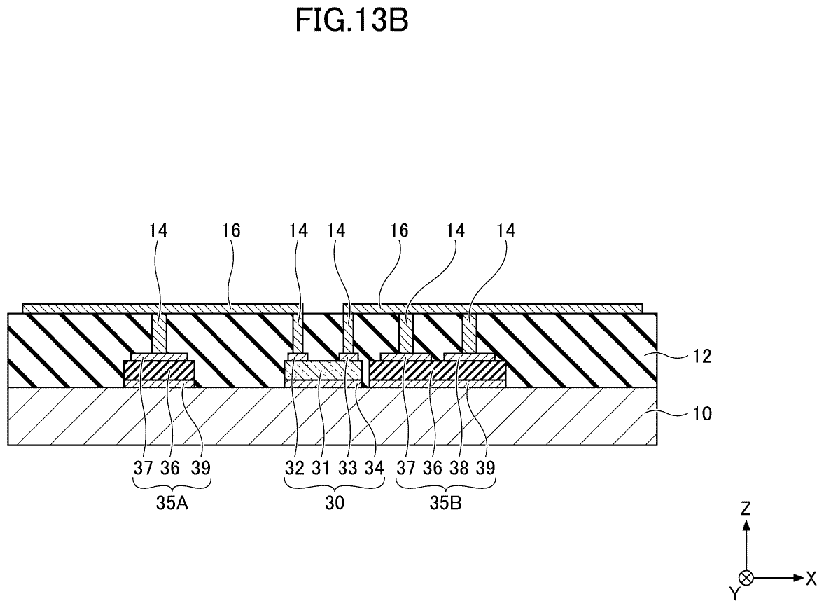

FIG. 13A is a plan view showing a method of manufacturing a semiconductor device according to the second embodiment, and FIG. 13B is an A-A cross-sectional view of FIG. 13A. As shown in FIGS. 13A and 13B, the mask layer 54 is peeled off. The metal layer 16A is removed using the metal layer 16B as a mask. Hereinafter, the metal layers 16A and 16B are collectively shown as the metal layer 16. The plurality of vias 14 connected to the electrode 32 are connected to the portion 17C. The plurality of vias 14 connected to the electrode 33 are connected to the portion 17D. The vias 14 connected to the electrode 37 of the passive element 35A are connected to the portion 17B. The vias 14 connected to the electrodes 37 and 38 of the passive element 35B are connected to the portion 17E.

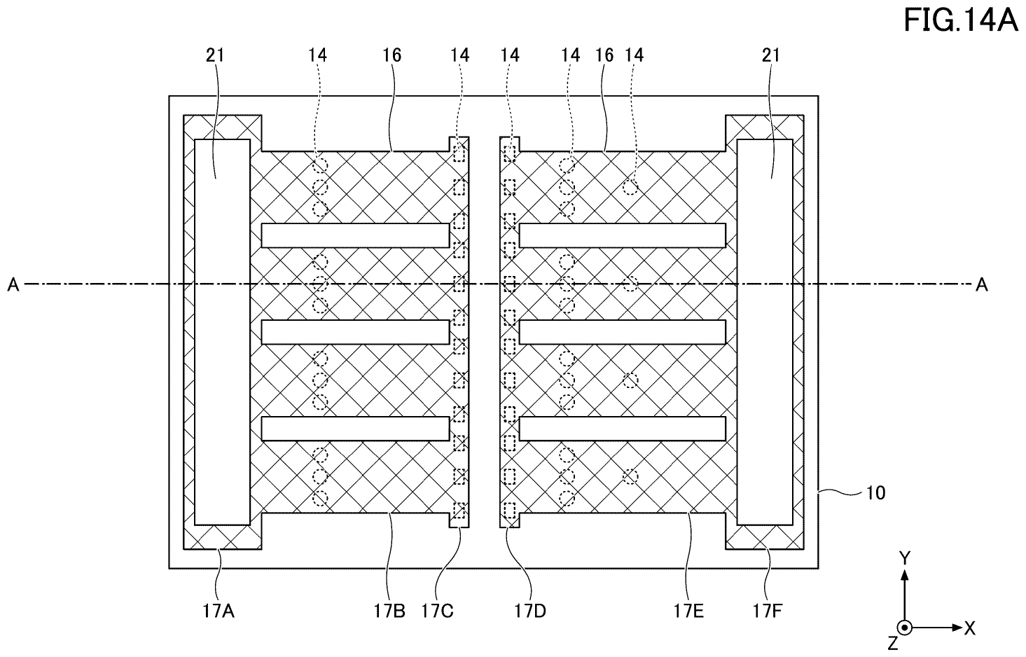

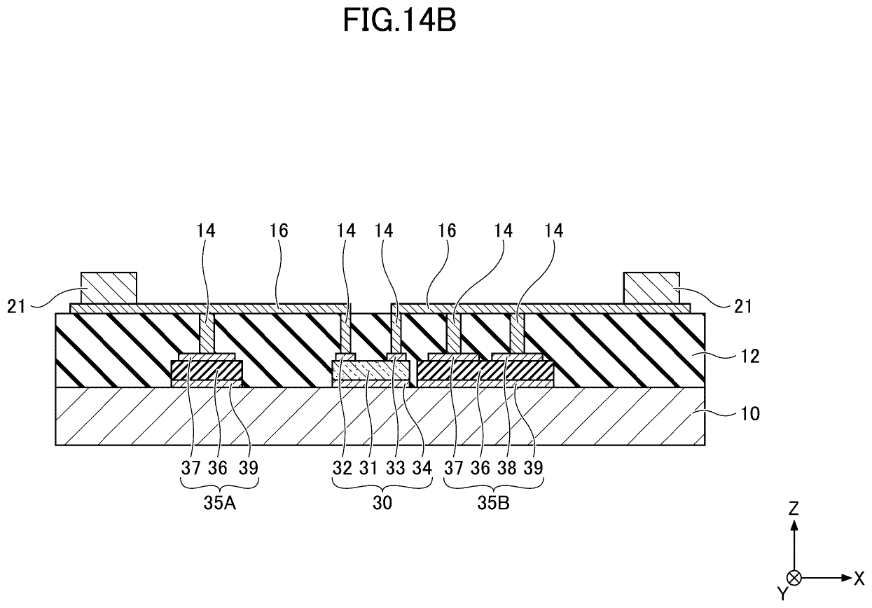

FIG. 14A is a plan view showing a method of manufacturing a semiconductor device according to the second embodiment, and FIG. 14B is an A-A cross-sectional view of FIG. 14A. As shown in FIGS. 14A and 14B, a conductive paste 21 are formed on the portions 17A and 17F of the metal layer 16 by using a printing method.

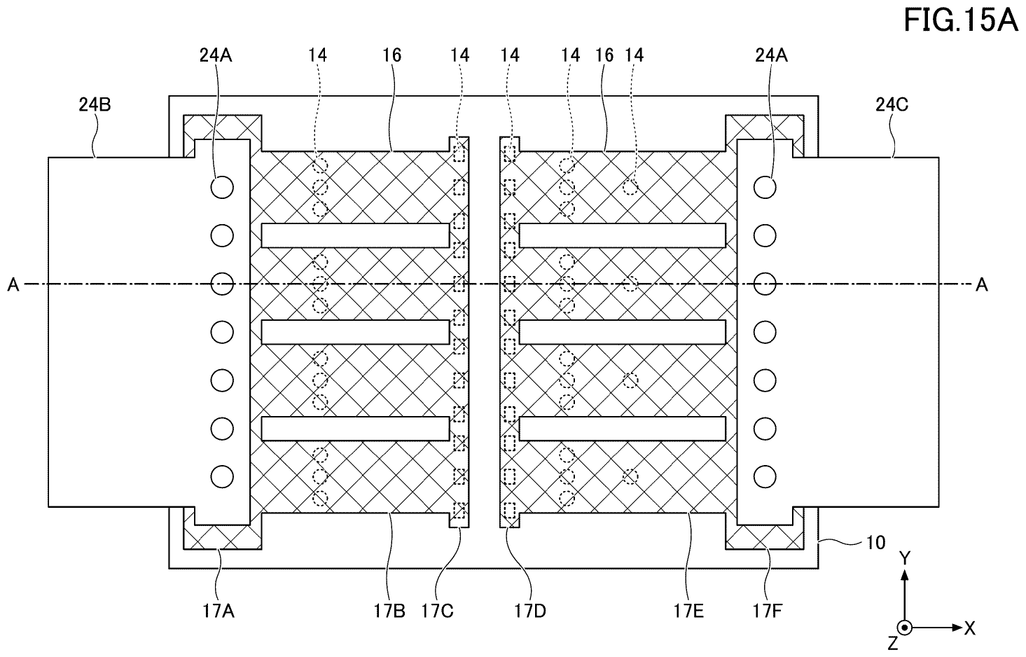

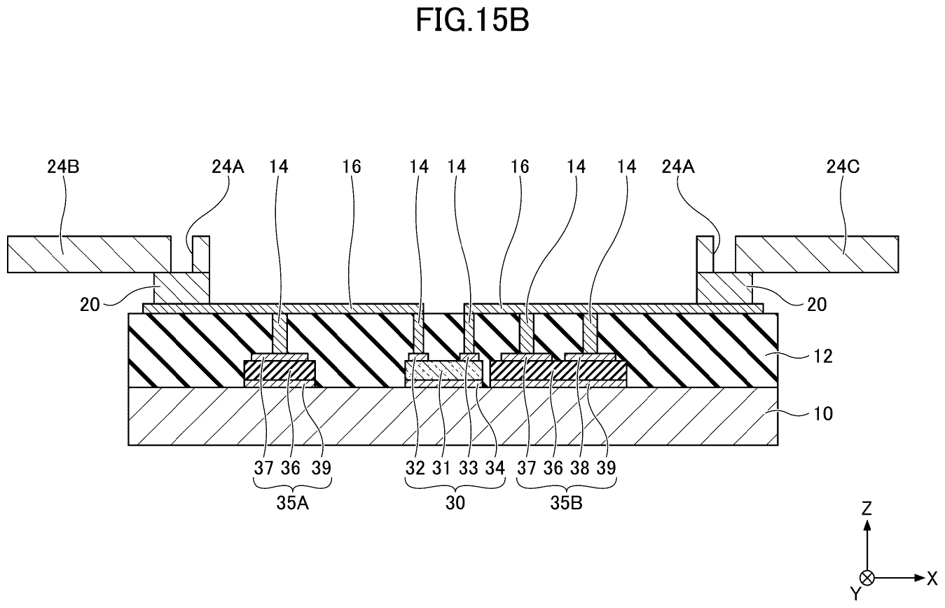

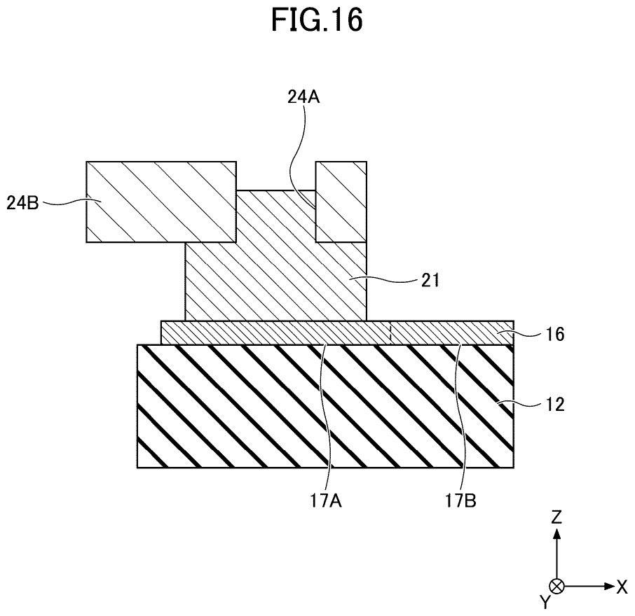

FIG. 15A is a plan view showing a method of manufacturing a semiconductor device according to the second embodiment, and FIG. 15B is an A-A cross-sectional view of FIG. 15A. FIG. 16 is an enlarged view of the bonding layer 20 and its vicinity of FIG. 15B. As shown in FIGS. 15A, 15B and 16, the leads 24B and 24C are attached onto the conductive paste 21 so that the holes 24A of the leads 24B and 24C are positioned on the conductive paste 21. The leads 24B and 24C are, for example, metal foils, and are processed into a desired shape in advance. The leads 24B and 24C are connected to the metal foil frame by connection bars. Thus, the leads 24B and 24C can be integrally attached to the conductive paste 21. At this time, the leads 24B and 24C are pressed against the conductive paste 21, so that the conductive paste 21 is introduced into at least a part of the hole 24A as shown in FIG. 16. Then, the conductive paste 21 is sintered by heat treatment to form the bonding layer 20.

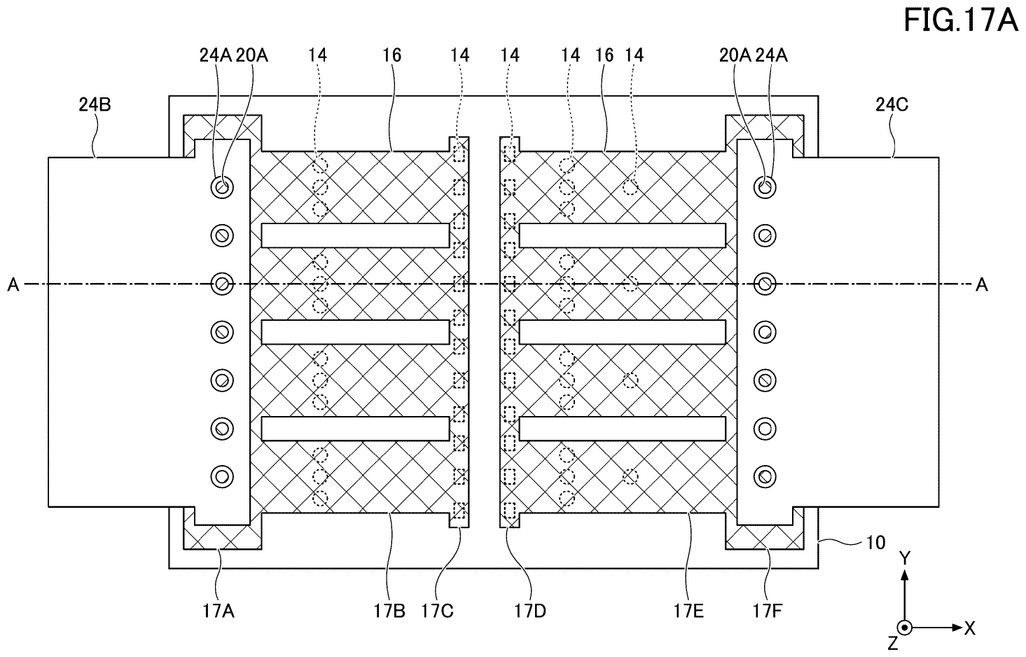

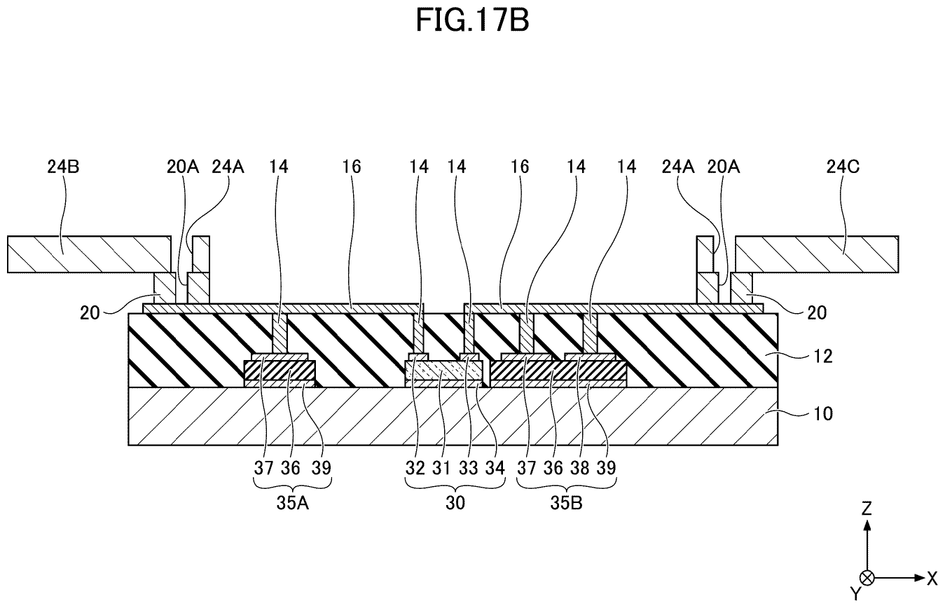

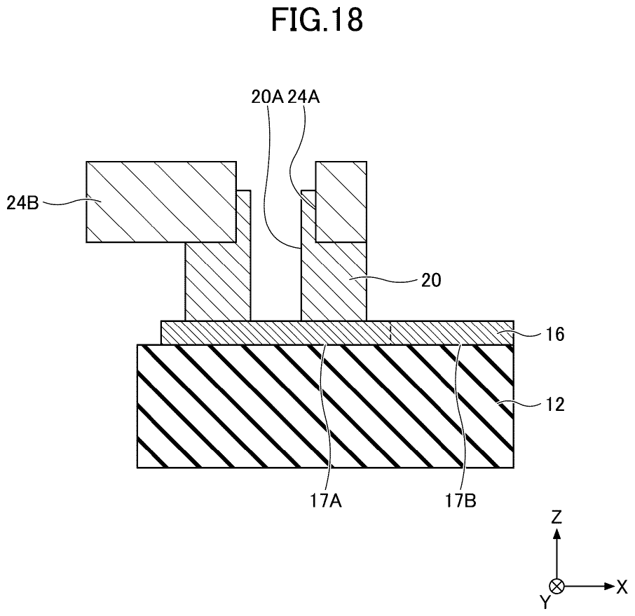

FIG. 17A is a plan view showing a method of manufacturing a semiconductor device according to the second embodiment, and FIG. 17B is an A-A cross-sectional view of FIG. 17A. FIG. 18 is an enlarged view of the bonding layer 20 and its vicinity of FIG. 17B. As shown in FIGS. 17A, 17B and 18, the hole 20A penetrating the bonding layer 20 is formed in the bonding layer 20 through the hole 24A. The hole 20A is formed by irradiating the inside of the hole 24A with laser light. The size of the hole 20A as viewed in the Z direction is smaller than the size of the hole 24A as viewed in the Z direction. The hole 20A exposes the surfaces of the portions 17A and 17F of the metal layer 16. In the portion 17A, one row of the plurality of holes 20A and 24A arrayed in the Y direction is provided, but a plurality of rows of the holes 20A and 24A arrayed in the Y direction may be arranged side by side in the X direction.

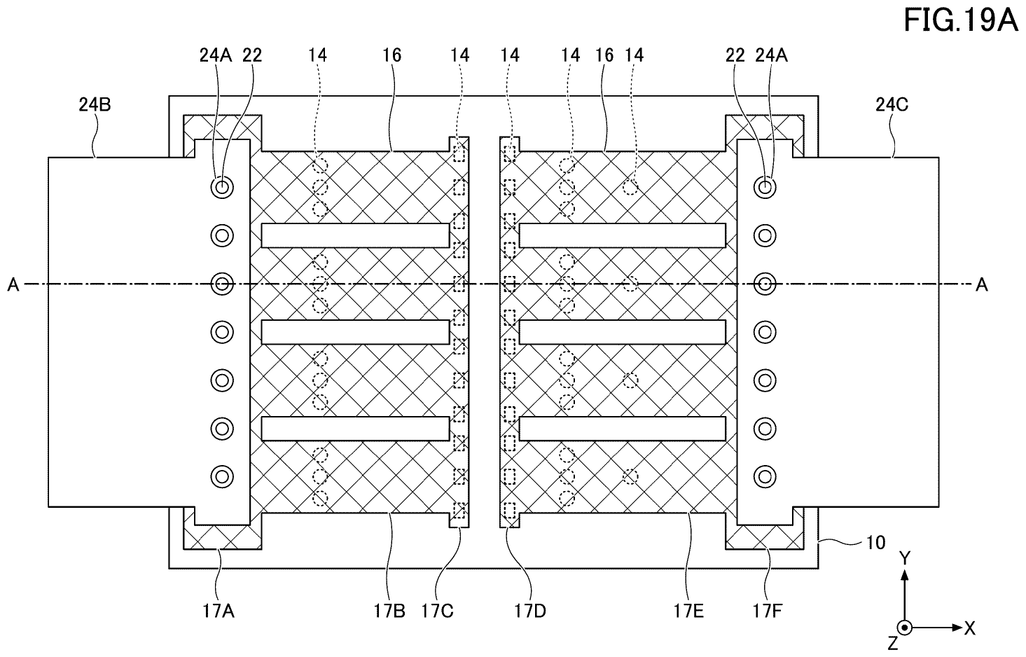

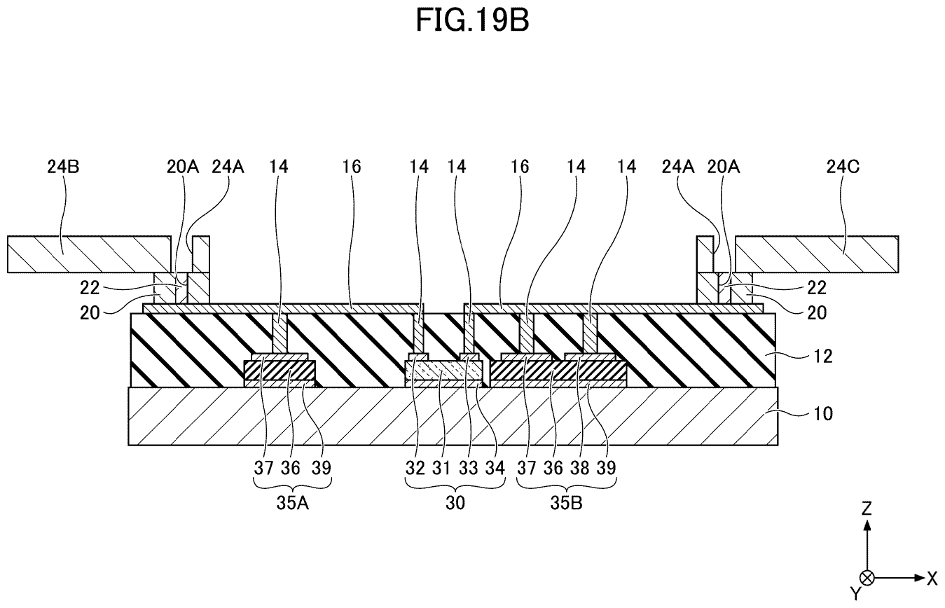

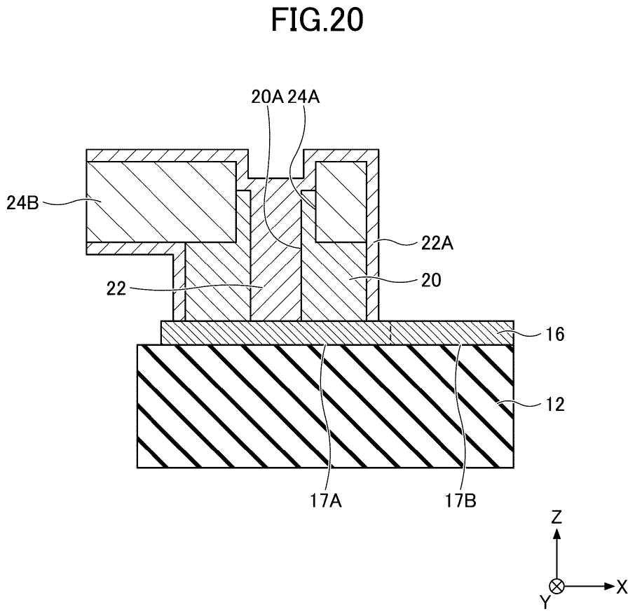

FIG. 19A is a plan view showing a method of manufacturing a semiconductor device according to the second embodiment, and FIG. 19B is an A-A cross-sectional view of FIG. 19A. FIG. 20 is an enlarged view of the bonding layer 20 and its vicinity of FIG. 19B. As shown in FIGS. 19A, 19B and 20, the metal layer 22 is formed in the holes 20A. The metal layer 22 is formed by electrolytic plating. The metal layer 22A made of the same material as the metal layer 22 is formed on the surfaces of the bonding layer 20 and the leads 24B and 24C by electrolytic plating. The lead 24B and the metal layer 22 are electrically connected by the metal layer 22A provided on the upper surface of the bonding layer 20 provided in the hole 24A.

Thereafter, the electronic component 40 (see FIG. 1) is mounted on the metal layer 16. Thereafter, as shown in FIGS. 4A and 4B, the insulating layer 18 is formed. The insulating layer 18 is formed by using, for example, a transfer molding method. Thereafter, the connection bars connecting the leads are cut for singulation. In this manner, the semiconductor device 102 according to the second embodiment is manufactured.

According to the second embodiment, as shown in FIGS. 14A and 14B, the bonding layer 20 is formed on the metal layer 16 (the first metal layer) electrically connected to the semiconductor element 30 and formed of a sintered metal or solder. As shown in FIGS. 15A to 16, the leads 24B and 24C are bonded onto the bonding layer 20. As shown in FIGS. 19A to 20, the metal layer 22 (the second metal layer) is formed to penetrate the bonding layer 20 so as to electrically connect the metal layer 16 to the leads 24B and 24C. Thus, the metal layer 22 for electrically connecting the metal layer 16 to the leads 24B and 24C can be formed.

A shown in FIGS. 17A to 18, the hole 20A is formed in the bonding layer 20 so as to be connected to the hole 24A (second hole) and penetrate the bonding layer 20, after the step of bonding the leads 24B and 24C and before the step of forming the metal layer 22. Thus, the hole 20A can be formed after the leads 24B and 24C are bonded to the bonding layer 20 and the bonding layer 20 is cured. When the hole 20A is formed in this manner, the hole 24A overlaps the hole 20A when viewed in the Z direction (the stacking direction of the bonding layer 20 and the leads 24B and 24C).

As shown in FIGS. 5B and 6, the hole 20A is smaller than the hole 24A when viewed in the Z direction, and the metal layer 22A (third metal layer) is provided on the bonding layer 20 in the hole 24A and electrically connects the metal layer 22 to the lead 24B. A third metal layer is provided. Thus, the metal layers 22 and 22A can electrically connect the metal layer 16 to the lead 24B.

The semiconductor element 30 for a high frequency signal has been described as an example of the second embodiment, but the semiconductor element 30 does not have to be for a high frequency signal. In the case of the semiconductor element 30 for a high frequency signal, high frequency characteristics are deteriorated if the electrical resistance between the leads 24B and 24C and the semiconductor element 30 is high. The metal layer 22 may be provided in the case where the semiconductor element 30 for a high frequency signal is provided as in the semiconductor device 102 of the second embodiment. This can improve high frequency characteristics.

The semiconductor element 30 includes the transistor Q1 that amplifies a high frequency signal input to the lead 24C (input lead) and outputs the amplified high frequency signal from the lead 24B (output lead). The portions 17A to 17C of the metal layer 16 include first interconnect that electrically connects the lead 24B and the transistor. The portions 17D to 17F of the metal layer 16 include second interconnect that electrically connects the lead 24C and the transistor. The passive elements 35A and 35B include capacitors C1 to C3 electrically connected to portions 17B and 17E, respectively. Thus, the transistor Q1 and the matching circuits 50 and 52 in FIG. 3 can be mounted on the base 10. In the high-frequency amplifier circuit, it is important to reduce the electrical resistance between the leads 24B and 24C and the semiconductor element 30 in order to improve the high-frequency characteristics. Thus, the metal layer 22 can be provided. In particular, in a high-frequency amplifier circuit with an output power of 10 W or more, it is important to reduce the electrical resistance between the leads 24B and 24C and the semiconductor element 30.

The embodiments disclosed herein are to be considered in all respects as illustrative and not restrictive. The scope of the present disclosure is defined by the appended claims rather than the foregoing description, and is intended to include all modifications within the scope and meaning equivalent to the claims.

What is claimed is:

1. A semiconductor device comprising:
a semiconductor element;
a first metal layer electrically connected to the semiconductor element;
a bonding layer bonded onto the first metal layer and formed of a sintered metal or solder;
a lead bonded onto the bonding layer; and
a second metal layer provided in a first hole penetrating the bonding layer, the second metal layer electrically connecting the first metal layer to the lead.

2. The semiconductor device according to claim 1,
wherein the second metal layer has a conductivity higher than a conductivity of the bonding layer.

3. The semiconductor device according to claim 1,
wherein the bonding layer is a sintered metal including a resin.

4. The semiconductor device according to claim 1,
wherein the lead has a second hole penetrating the lead, and
wherein the second hole overlaps the first hole when viewed in a stacking direction of the second metal layer and the lead.

5. The semiconductor device according to claim 4,
wherein the first hole is smaller than the second hole when viewed in the stacking direction, and
wherein the semiconductor device includes a third metal layer provided on the bonding layer in the second hole and electrically connecting the second metal layer to the lead.

6. The semiconductor device according to claim 1, further comprising:
a base on which the semiconductor element is mounted, the base being conductive; and
an insulating layer provided on the base so as to cover the semiconductor element, the first metal layer being provided on an upper surface of the insulating layer.

7. The semiconductor device according to claim 6, further comprising:
an electronic component provided on the insulating layer and electrically connected to the lead or the semiconductor element.

8. The semiconductor device according to claim 6, further comprising:
a passive element mounted on the base,
wherein the lead includes an input lead and an output lead,
wherein the semiconductor element includes a transistor configured to amplify a high frequency signal input to the input lead and output an amplified high frequency signal from the output lead,
wherein the first metal layer includes a first interconnect electrically connecting the input lead to the transistor and a second interconnect electrically connecting the output lead to the transistor, and
wherein the passive element includes a capacitor electrically connected to the first interconnect or the second interconnect.

9. The semiconductor device according to claim 1,
wherein the semiconductor element is an element for a high frequency signal.

10. A method of manufacturing a semiconductor device, the method comprising:
forming a bonding layer formed of a sintered metal or solder on a first metal layer electrically connected to a semiconductor element;
bonding a lead onto the bonding layer; and
forming a second metal layer in a first hole penetrating the bonding layer so as to electrically connect the first metal layer to the lead.

11. The method of manufacturing a semiconductor device according to claim 10,
wherein the lead has a second hole penetrating the lead, and
wherein the method of manufacturing the semiconductor device includes forming the first hole in the bonding layer so as to be connected to the second hole and penetrate the bonding layer, after the bonding the lead and before the forming the second metal layer.
